(19) United States
(12) Patent Application Publication
(10) Pub. No.: US 2025/0326961 A1
(43) Pub. Date: Oct. 23, 2025

(54) Slurry Composition for Low-K Film Polishing

(71) Applicant: KCTECH CO., LTD., Gyeonggi-do (KR)

(72) Inventors: Jin Myung HWANG, Gyeonggi-do (KR); Jun Pyo LEE, Gyeonggi-do (KR); Jun Ha HWANG, Gyeonggi-do (KR); Jae Hak LEE, Gyeonggi-do (KR)

(21) Appl. No.: 19/177,158

(22) Filed: Apr. 11, 2025

(30) Foreign Application Priority Data
Apr. 18, 2024 (KR) 10-2024-0052310

(51) Int. Cl. C09K 3/14

(52) U.S. Cl. CPC C09K 3/1463

(57) ABSTRACT

Provided is a slurry composition for low-k film polishing, the slurry composition including ceria abrasive particles, a dispersant, a SiN polishing inhibitor, and a low-k booster, in which the dispersant is monomolecular organic acid.

### RELATED APPLICATION DATA

This application claims the benefit of Korean Patent Application No. 10-2024-0052310 filed on Apr. 18, 2024, in the Korean Intellectual Property Office, the entire disclosure of which is incorporated herein by reference for all purposes.

### FIELD OF DISCLOSURE

One or more embodiments relate to a slurry composition for low-k film polishing.

### BACKGROUND

Wafers are used to form integrated circuits in microelectronic devices. Wafers contain materials such as silicon, and have areas patterned for deposition of different materials having insulating, conductive, or semi-conductive properties in the wafers. To achieve accurate patterning, the excessive amount of materials used to form layers on the wafers should be removed. Additionally, to manufacture functional and reliable circuits, it is important to manufacture flat or planar surfaces of the microelectronic wafers prior to subsequent processing. Therefore, it is necessary to remove and/or polish specific surfaces of the microelectronic device wafers.

Chemical Mechanical Polishing (CMP) is a process in which any material is removed from a surface of a microelectronic device wafer and the surface is polished by a combination of a physical process such as polishing and a chemical process such as oxidation or chelation. In its most basic form, CMP involves applying a slurry, such as a solution of an abrasive and an active compound, to a polishing pad, which then buffs away, planarizes, and polishes the surface of the microelectronic device wafer. Additionally, in the manufacturing of integrated circuits, the CMP slurry should be capable of preferentially removing films including composite layers of metals and other materials, so that a highly flat surface may be generated on the wafer for subsequent lithography or patterning, etching, and thin film processing.

Meanwhile, due to the miniaturization and high integration of semiconductor devices, a gap between metals is narrowing, and the use of low-k materials with low dielectric constant as insulating films is increasing. However, since the low-k film has hydrophobic properties, it is difficult to secure a high removal rate with the existing polishing slurry composition.

### SUMMARY OF DISCLOSURE

Embodiments provide a slurry composition for low-k film polishing capable of improving a removal rate of a low-k film by hydrophilizing a low-k film surface by a positively charged ceria slurry composition, to which a hydrophilic low-k booster is applied, and increasing the interaction between abrasive particles and the low-k film, while controlling a selectivity of the low-k film and a SiN film by reducing a removal rate of the SiN film by inducing N—H hydrogen bonding for nitrogen atoms on the SiN film by a SiN polishing inhibitor.

However, technical goals to be achieved are not limited to those described above, and other goals not mentioned above may be clearly understood by one of ordinary skill in the art from the following description.

According to an aspect, there is provided a slurry composition for low-k film polishing, the slurry composition including ceria abrasive particles, a dispersant, a SiN polishing inhibitor, and a low-k booster, wherein the dispersant is monomolecular organic acid.

Additional aspects of embodiments will be set forth in part in the description which follows and, in part, will be apparent from the description, or may be learned by practice of the disclosure.

According to embodiments, the slurry composition for low-k film polishing has the effect of securing a high low-k removal rate of about 2,000 to 3,000 Å/min by hydrophilizing the low-k surface and increasing the interaction between the abrasive particles and the low-k film, while securing a selectivity for the low-k film and the SiN film of about 50:1 (low-k: SiN) or more.

It should be understood that the effects of the present disclosure are not limited to the above-described effects, but are construed as including all effects that may be inferred from the configurations and features described in the following description or claims of the present disclosure.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a graph showing a change in a low-k removal rate according to an amount of a low-k booster added;

FIG. 2 is a graph showing a change in a removal rate according to sizes and types of abrasive particles;

FIG. 3 is a graph showing a change in a removal rate according to an amount of a SiN polishing inhibitor added;

FIG. 4 is a graph showing a change in a removal rate according to a change in pH; and

FIG. 5 is a graph showing a change in a removal rate according to a type of a dispersant.

### DETAILED DESCRIPTION

Hereinafter, embodiments will be described in detail with reference to the accompanying drawings. However, various alterations and modifications may be made to the embodiments. Here, the embodiments are not construed as limited to the disclosure. The embodiments should be understood to include all changes, equivalents, and replacements within the idea and the technical scope of the disclosure.

The terminology used herein is for the purpose of describing particular embodiments only and is not to be limiting of the embodiments. The singular forms “a,” “an,” and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments belong. Terms, such as those defined in commonly used dictionaries, are to be interpreted as having a meaning that is consistent with their meaning in the context of the relevant art and the present disclosure, and are not to be interpreted in an idealized or overly formal sense unless expressly so defined herein.

When describing the embodiments with reference to the accompanying drawings, like reference numerals refer to like components and a repeated description related thereto will be omitted. In the description of embodiments, detailed description of well-known related structures or functions will be omitted when it is deemed that such description will cause ambiguous interpretation of the present disclosure.

In addition, the terms first, second, A, B, (a), and (b) may be used to describe constituent elements of the embodiments. These terms are used only for the purpose of discriminating one component from another component, and the nature, the sequences, or the orders of the components are not limited by the terms.

A component, which has the same common function as a component included in any one embodiment, will be described by using the same name in other embodiments. Unless disclosed to the contrary, the description of any one embodiment may be applied to other embodiments, and the specific description of the repeated configuration will be omitted.

It will be understood that when a certain part “includes” a certain component, the part does not exclude another component but may further include another component.

The present disclosure relates to a slurry composition for low-k film polishing, the slurry composition including ceria abrasive particles, a dispersant, a SiN polishing inhibitor, and a low-k booster, wherein the dispersant is monomolecular organic acid. In the present disclosure, low-k refers to a low dielectric constant, and specifically refers to a value of the dielectric constant (k) of 3.9 or less. In addition, a low-k film refers to a film on a semiconductor wafer made of a material with the low dielectric constant as described above. Specifically, the low-k film may be formed of a material in which carbon (C) is doped in silicon oxide (SiO₂) using a gas containing a methyl group (CH₃).

According to an embodiment, the ceria abrasive particles may be calcined ceria abrasive particles or colloidal ceria abrasive particles.

In a case of the calcined ceria abrasive particles, a cerium raw material precursor (e.g., a precursor such as cerium carbonate) is calcined using a general solid phase synthesis method to prepare a ceria powder. The ceria powder may be slurried by top-down milling using beads. The top-down milling process refers to a milling process of pulverizing particles from a large size to a small size. At this time, the beads may have a size of 0.01 millimeters (mm) to 1.0 mm, and desirably, 0.05 mm to 0.2 mm.

A grain size of the calcined ceria abrasive particles may be 20 nanometers (nm) to 60 nm, 20 nm to 50 nm, or 30 nm to 50 nm. Also, the lower limit of the size when the calcined ceria abrasive particles are slurried may be 50 nm, 60 nm, 70 nm, 80 nm, or 90 nm, and the upper limit of the size when the calcined ceria abrasive particles are slurried may be 150 nm, 140 nm, 130 nm, 120 nm, or 110 nm. The abrasive particle size refers to an average value of particle diameters of a plurality of particles within the field of view in which the size may be measured by scanning electron microscope analysis, Brunauer-Emmett-Teller (BET) analysis, or dynamic light scattering. When the size of the calcined ceria abrasive particles exceeds the upper limit, a desired removal rate may not be obtained and defects or scratches may occur after polishing. When the size thereof is less than the lower limit, a problem regarding a decrease in the removal rate may occur due to insufficient polishing.

The colloidal ceria abrasive particles may be synthesized from a cerium precursor using a hydrothermal synthesis method, a sol-gel method, a coprecipitation method, a spray drying method, a thermal evaporation method, or the like, and liquid synthesis particles may be dispersed by mild milling using beads to obtain a slurry. At this time, a homogenizer may be additionally used to improve dispersibility, and the beads may have a size of 0.005 mm to 0.5 mm, desirably, 0.01 mm to 0.1 mm.

A grain size of the colloidal ceria abrasive particles may be 5 nm to 30 nm, 5 nm to 25 nm, 5 nm to 20 nm, 10 nm to 30 nm, 10 nm to 25 nm, 10 nm to 20 nm, 15 nm to 30 nm, 15 nm to 25 nm, or 15 nm to 20 nm. Also, the lower limit of the size when the colloidal ceria abrasive particles are slurried may be 20 nm, 30 nm, 40 nm, or 50 nm, and the upper limit of size when colloidal ceria abrasive particles are slurried may be 100 nm, 90 nm, 80 nm, or 70 nm. The abrasive particle size refers to an average value of particle diameters of a plurality of particles within the field of view in which the size may be measured by scanning electron microscope analysis, BET analysis, or dynamic light scattering. When the size of the colloidal ceria abrasive particles exceeds the upper limit, a desired removal rate may not be obtained and defects or scratches may occur after polishing. When the size thereof is less than the lower limit, a problem regarding a decrease in the removal rate may occur due to insufficient polishing.

According to an embodiment, the ceria abrasive particles may be included in an amount of 0.1 wt % to 10 wt %, desirably, 0.1 wt % 5 wt %, 0.1 wt % 1 wt %, or 1 wt % to 5 wt % based on a total weight of the slurry composition.

When the content of the ceria abrasive particles is less than the lower limit, a problem regarding a decrease in a polishing speed may occur, and when the content thereof exceeds the upper limit, surface defects may occur due to adsorption of particles remaining on a surface thereof.

According to an embodiment, the dispersant is monomolecular organic acid which may be added to disperse abrasive particles within a slurry, may specifically include one or more selected from the group consisting of organic acid having a structure represented by Chemical Formula 1, aromatic alpha hydroxy carboxylic acid, and pyridine carboxylic acid.

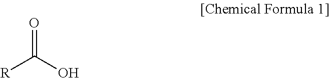

(where R is H or a methyl group.)

Specifically, the organic acid may include one or more selected from the group consisting of formic acid, acetic acid, mandelic acid, picolinic acid, nicotinic acid, isonicotinic acid, and isomers thereof, and may include desirably one or more selected from the group consisting of formic acid, acetic acid, and picolinic acid. For example, when the calcined ceria abrasive particles are used, picolinic acid may be used as the dispersant, and when the colloidal ceria abrasive particles are used, formic acid or acetic acid (picolinic acid may also be used) may be used as the dispersant. When formic acid or acetic acid is used as the dispersant, not only a high low-k removal rate may be secured, but there is also the advantage of securing a high polishing selectivity of a low-k film for a SiN film. In particular, when formic acid is used, a higher removal rate may be secured for a low-k film.

According to an embodiment, the dispersant may be included in an amount of 0.1 wt % to 30 wt % based on the total weight of the slurry composition, and may be included in an amount of desirably 0.5 wt % to 30 wt %, 0.5 wt % to 10 wt %, 1 wt % to 10 wt %, 1 wt % to 7 wt %, 3 wt % to 7 wt %, 10 wt % to 30 wt %, or 15 wt % to 25 wt %. When the content of the dispersant is less than the lower limit, it is difficult to secure particle dispersibility and phase stability, and when the content thereof exceeds the upper limit, the dispersion stability may deteriorate, which makes it difficult to implement polishing performance.

According to an embodiment, the slurry composition of the present disclosure may further include a cationic polymer. The cationic polymer may serve to adjust the removal rate of the low-k film to an appropriate level according to the content, thereby improving the polishing performance in a pattern wafer. Specifically, the cationic polymer may be in the form of quaternary ammonium.

According to an embodiment, the cationic polymer may include one or more selected from the group consisting of poly(2-methacryloxyethyl)trimethylammonium chloride; poly(acrylamide 2-methacryloxyethyltrimethyl ammonium chloride); poly[2-(dimethylamino)ethyl methacrylate methyl chloride]; poly[3-acrylamidopropyl trimethylammonium chloride]; poly[3-methacrylamidopropyl trimethylammonium chloride]; poly[bis(2-chloroethyl) ether-alt-1,3-bis[3-(dimethylamino)propyl]urea]; a copolymer of acrylamide and quaternized dimethylammoniumethyl methacrylate; an acrylamide-dimethylaminoethyl methacrylate methyl chloride copolymer; a copolymer of vinylpyrrolidone and quaternized dimethylaminoethyl methacrylate; and a copolymer of vinylpyrrolidone and methacrylamidopropyl trimethylammonium, and may include desirably poly(2-methacryloxyethyl)trimethylammonium chloride; or poly(acrylamide 2-methacryloxyethyltrimethyl ammonium chloride).

According to an embodiment, the cationic polymer may be included in an amount of 0.001 wt % to 0.1 wt % based on the total weight of the slurry composition, and may be included in an amount of desirably 0.005 wt % 0.05 wt %. When the content of the cationic polymer is less than the lower limit, a problem of deterioration in polishing performance of the pattern wafer may occur. When the content thereof exceeds the upper limit, a problem of an excessive decrease in the removal rate of the low-k film may occur.

According to an embodiment, the slurry composition according to the present disclosure may further include organic acid as a pH buffer. The pH buffer is used to prevent a rapid change in pH that occurs when preparing a composition by mixing a pH adjuster or the like, and the pH buffer may specifically include at least one selected from the group consisting of formic acid, acetic acid, benzoic acid, oxalic acid, succinic acid, malic acid, maleic acid, malonic acid, citric acid, lactic acid, tricarballyic acid, tartaric acid, aspartic acid, glutaric acid, adipic acid, suberic acid, fumaric acid, phthalic acid, and salts thereof, and may be desirably formic acid.

According to an embodiment, the pH buffer may be included in an amount of 0.01 wt % to 1 wt % based on the total weight of the slurry composition, and may be include in an amount of desirably 0.05 wt % 0.5 wt %. When the content of the pH buffer exceeds the upper limit, a problem of deriving the agglomeration of particles may occur, and when the content thereof is less than the lower limit, a problem of the decrease in the low-k removal rate may occur.

According to an embodiment, the slurry composition of the present disclosure may include a SiN polishing inhibitor. The SiN polishing inhibitor in the composition may induce N—H hydrogen bonding to nitrogen atoms of the SiN film to reduce the removal rate of the SiN film, and secure the polishing selectivity of the low-k film for the SiN film. Specifically, the SiN polishing inhibitor may include one or more selected from the group consisting of maltitol, lactitol, threitol, erythritol, ribitol, xylitol, arabitol, adonitol, sorbitol, talitol, mannitol, iditol, allodulcitol, dulcitol, galactitol, sedoheptitol, and perseitol, and may include desirably sorbitol. When sorbitol is used, it has the advantage of inhibiting SiN polishing in a wide pH range from pH 2 to 12.

According to an embodiment, the SiN polishing inhibitor may be included in an amount of 0.1 wt % to 5 wt % based on the total weight of the slurry composition, and may be included in an amount of desirably 0.5 wt % to 3 wt %, and more desirably 0.5 wt % to 2 wt %, or 1 wt % to 2 wt %. When the content of the SiN polishing inhibitor is less than the lower limit, a problem of not securing a sufficient polishing selectivity due to an increase in the removal rate for the SiN film may occur, and when the content thereof exceeds the upper limit, a problem of the decrease in the low-k removal rate may occur.

The slurry composition according to the present disclosure may include a low-k booster to improve the removal rate for the low-k film, and the low-k booster may be an amine-based compound. A hydrophilic low-k booster may hydrophilize a surface of a hydrophobic low-k film, and increase an interaction between abrasive particles and the low-k film, thereby improving the removal rate of the low-k film. Specifically, the low-k booster may include one or more selected from the group consisting of triethanolamine, aminomethyl propanol, ammonium hydroxide, lysine, arginine, and histidine, and may be desirably triethanolamine. When triethanolamine is used, it is easy to control the low-k removal rate.

According to an embodiment, the low-k booster may be included in an amount of 0.01 wt % to 1 wt % based on the total weight of the slurry composition, and may be included in an amount of desirably 0.1 wt % to 1 wt %, more desirably 0.3 wt % to 1 wt %, or 0.4 wt % to 0.7 wt %. When the content of the low-k booster is less than the lower limit, the removal rate of the low-k film may decrease due to insufficient hydrophilization of the low-k film, and when the content thereof exceeds the upper limit, the effect of increasing the low-k removal rate is minimal, while a problem of a decrease in the removal rate of the low-k film may occur.

According to an embodiment, the pH of the slurry composition of the present disclosure may be 3 to 7, desirably 3.5 to 6.5, more desirably 4 to 6, and still more desirably 4.5 to 5.5. When the pH exceeds the upper limit, it approaches the isoelectric point, and problems of the decrease in the slurry stability and removal rate may occur. When the pH thereof is less than the lower limit, a problem of the decrease in the low-k removal rate may occur due to the insufficient content of the low-k booster.

According to an embodiment, the slurry composition of the present disclosure may be provided in a one-component or two-component form depending on the purpose of use.

When provided in the two-component form, a polishing solution containing abrasive particles and a dispersant and an additive solution containing a SiN polishing inhibitor and a low-k booster may be prepared separately and mixed for use immediately before polishing. At this time, the additive solution may further include a cationic polymer and a pH buffer.

Hereinafter, the present disclosure will be described in more detail with reference to examples. The following examples are provided for the purpose of illustrating the present disclosure and are not intended to limit the scope of the present disclosure.

### EXAMPLES

### 1. Confirmation of Low-k Removal Rate According to Amount of Low-k Booster Added

### Example 1

A polishing solution containing 2.5 wt % of calcined ceria abrasive particles having a size of 100 nm, 20 wt % of picolinic acid as the dispersant, and the remainder of water was prepared.

An additive solution with a pH of 4.8 containing 0.015 wt % of poly(2-methacryloxyethyl)trimethylammonium chloride as the cationic polymer, 1 wt % of sorbitol as the SiN polishing inhibitor, 0.175 wt % of formic acid as the pH buffer, 0.4 wt % of triethanolamine as the low-k booster, and the remainder of water was prepared.

The polishing solution and the additive solution were mixed to prepare a slurry composition for low-k film polishing.

### Example 2

A slurry composition for low-k film polishing was prepared in the same manner as in Example 1 except that 0.55 wt % of triethanolamine was added as the low-k booster to adjust the pH to 5.8.

### Example 3

A slurry composition for low-k film polishing was prepared in the same manner as in Example 1 except that 0.7 wt % of triethanolamine was added as the low-k booster to adjust the pH to 6.5.

### Example 4

A slurry composition for low-k film polishing was prepared in the same manner as in Example 1 except that 0.85 wt % of ammonium hydroxide was added as the low-k booster to adjust the pH to 7.5.

### Test Example 1

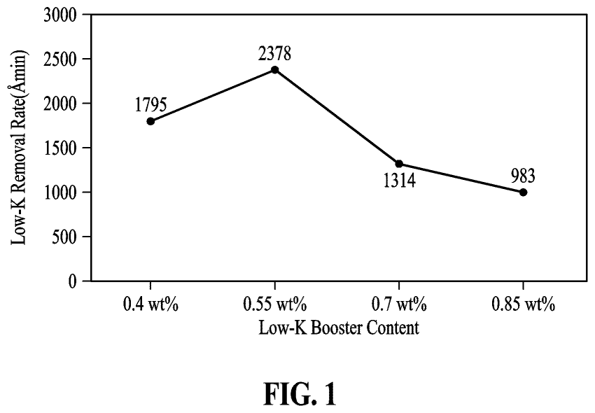

For the prepared compositions of Examples 1 to 4, the removal rate of a low-k film was measured under the following conditions, and a change in the removal rate according to the amount of low-k booster added was shown in FIG. 1.

### Polishing Evaluation Conditions

1. Polishing equipment: CTS AP-300
2. Wafer: Advantech Black Diamond 1
3. Carrier pressure: 2 psi
4. Spindle speed: 87 rpm
5. Platen speed: 93 rpm
6. Flow rate: 200 ml/min
7. Polishing time: 1 min

Referring to FIG. 1, the removal rate for the low-k film increases greatly by adding the low-k booster, however, when the amount of low-k booster added increases beyond a predetermined content, it may be confirmed that the pH increases and the removal rate tends to decrease. Therefore, it is preferable that the low-k booster is used in an amount that may adjust the pH of the additive solution to the range of 4.8 to 6.5.

### 2. Comparison of Removal Rates According to Particle Size and Type

### Example 5

A polishing solution with a pH of 4 containing 2.5 wt % of calcined ceria abrasive particles having a size of 150 nm, 20 wt % of picolinic acid as the dispersant, and the remainder of water was prepared.

An additive solution with a pH of 5.8 containing 0.015 wt % of poly(2-methacryloxyethyl)trimethylammonium chloride as the cationic polymer, 1 wt % of sorbitol as the SiN polishing inhibitor, 0.175 wt % of formic acid as the pH buffer, 0.5 wt % of triethanolamine as the low-k booster, and the remainder of water was prepared.

The polishing solution and the additive solution were mixed to prepare a slurry composition for low-k film polishing with a pH of 5. At this time, the solid content of the abrasive particles in the slurry composition was 0.3 to 0.5 wt %.

### Example 6

A slurry composition for low-k film polishing was prepared in the same manner as in Example 5, except that calcined ceria abrasive particles having a size of 100 nm were used.

### Example 7

A slurry composition for low-k film polishing was prepared in the same manner as in Example 5, except that 2.5 wt % of colloidal ceria abrasive particles having a size of 120 nm and 5 wt % of acetic acid as the dispersant were used.

### Example 8

A slurry composition for low-k film polishing was prepared in the same manner as in Example 7, except that colloidal ceria abrasive particles having a size of 100 nm were used.

### Example 9

A slurry composition for low-k film polishing was prepared in the same manner as in Example 7, except that colloidal ceria abrasive particles having a size of 70 nm were used.

### Comparative Example 1

A slurry composition for low-k film polishing containing 4 wt % of silica particles (negative charge, particle size of 20 nm), 0.1 wt % of dextrin, and the remainder of water was prepared.

### Comparative Example 2

A slurry composition for low-k film polishing was prepared in the same manner as in Example 5, except that commercially available colloidal ceria particles (HC-60) were used.

### Test Example 2

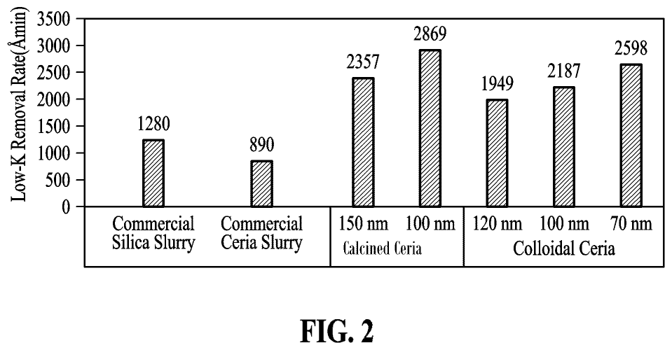

For each of the slurry compositions for polishing of Examples 5 to 9, the removal rate for the low-k film was measured in the same manner as in the Test Example 1, and the results thereof were shown in Table 1 and FIG. 2.

TABLE 1

| | Comparative | Comparative | Example | Example | Example | Example | Example |
|---|---|---|---|---|---|---|---|
| | Example 1 | Example 2 | 5 | 6 | 7 | 8 | 9 |
| Low-k | Silica | Colloidal | Calcined | Calcined | Colloidal | Colloidal | Colloidal |
| removal | particles | ceria | ceria | ceria | ceria | ceria | ceria |
| rate | | particles | particles | particles | particles | particles | particles |
| | | (HC-60) | 150 nm | 100 nm | 120 nm | 100 nm | 70 nm |
| (Å/min) | 1280 | 890 | 2357 | 2869 | 1949 | 2187 | 2598 |

Referring to Table 1 and FIG. 2, it may be confirmed that the slurry composition according to the examples of the present disclosure, in which the calcined ceria particles or the colloidal ceria particles are used, is excellent in terms of the low-k removal rate, compared to a case where the silica particles or commercially available colloidal ceria particles are used. Particularly, it may be confirmed that, when the calcined ceria abrasive particles are used, an excellent removal rate is obtained compared to a case of the colloidal ceria particles, even if the particles have the same size. Also, for each ceria particle, it may be seen that, as the size of the abrasive particles decreases, the removal rate tends to increase.

### 3. Effect of Decrease in SiN Removal Rate by Application of SiN Polishing Inhibitor

### Example 10

A polishing solution containing 2.5 wt % of calcined ceria abrasive particles having a size of 100 nm, 20 wt % of picolinic acid as the dispersant, and the remainder of water was prepared.

An additive solution containing 0.015 wt % of poly(2-methacryloxyethyl)trimethylammonium chloride as the cationic polymer, 0.5 wt % of sorbitol as the SiN polishing inhibitor, 0.175 wt % of formic acid as the pH buffer, 0.5 wt % of triethanolamine as the low-k booster, and the remainder of water was prepared.

The polishing solution and the additive solution were mixed to prepare a slurry composition for low-k film polishing with a pH of 5. At this time, the solid content of the abrasive particles in the slurry composition was 0.3 to 0.5 wt %.

### Example 11

A slurry composition for low-k film polishing was prepared in the same manner as in Example 10 except that 1 wt % of sorbitol was added as the SiN polishing inhibitor.

### Example 12

A slurry composition for low-k film polishing was prepared in the same manner as in Example 10 except that 1.5 wt % of sorbitol was added as the SiN polishing inhibitor.

### Comparative Example 3

A slurry composition for low-k film polishing was prepared in the same manner as in Example 10 except that the SiN polishing inhibitor was not added.

### Test Example 3

For each of the slurry compositions of Examples 10 to 12 and Comparative Example 3, the removal rate for the SiN film was measured, and the removal rate for the low-k film was measured in the same conditions as in the Test Example 1.

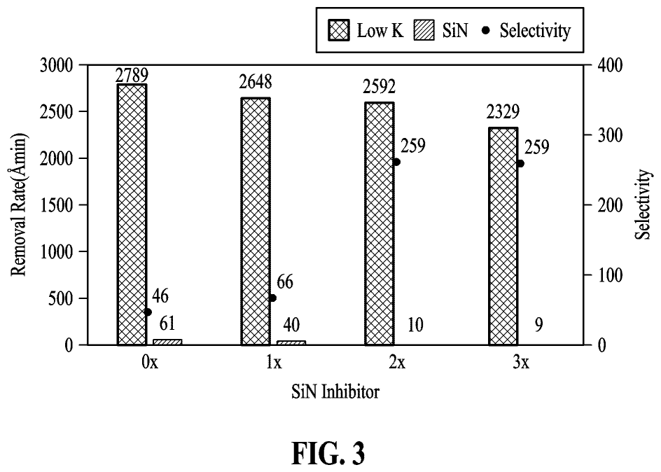

The polishing selectivity of the low-k film to the SiN film (low-k/SiN) was calculated and results thereof were shown in Table 2 below and FIG. 3.

TABLE 2

| | Comparative | | | |
|---|---|---|---|---|
| | Example 3 | Example 10 | Example 11 | Example 12 |
| Low-k (Å/min) | 2789 | 2648 | 2592 | 2329 |
| SiN (Å/min) | 61 | 40 | 10 | 9 |
| Selectivity | 46 | 66 | 259 | 259 |

Referring to Table 2 and FIG. 3, it may be confirmed that, as the amount of SiN polishing inhibitor added increases, the low-k removal rate decreases, however, the removal rate for the SiN film decreases at a greater rate, and the polishing selectivity of the low-k film to the SiN film significantly increases. Particularly, when the amount of SiN polishing inhibitor is increased from 0.5 wt % to 1 wt %, the polishing selectivity increases rapidly from 66 to 259, while the decrease in the removal rate for low-k films is not large, which shows the excellent effect.

### 4. Changes in SiN Removal Rate and Low-k Removal Rate According to pH Control

### Example 13

A polishing solution containing 2.5 wt % of calcined ceria abrasive particles having a size of 100 nm, 20 wt % of picolinic acid as the dispersant, and the remainder of water was prepared.

An additive solution containing 0.015 wt % of poly(2-methacryloxyethyl)trimethylammonium chloride as the cationic polymer, 1 wt % of sorbitol as the SiN polishing inhibitor, 0.175 wt % of formic acid as the pH buffer, 0.5 wt % to 0.7 wt % of triethanolamine as the low-k booster, and the remainder of water was prepared.

The polishing solution and the additive solution were mixed to prepare a slurry composition for low-k film polishing with a pH of 4.

### Example 14

A slurry composition for low-k film polishing was prepared in the same manner as in Example 13 except that the amount of triethanolamine added was adjusted to adjust the pH of the slurry composition to 5.

### Example 15

A slurry composition for low-k film polishing was prepared in the same manner as in Example 13 except that the amount of triethanolamine added was adjusted to adjust the pH of the slurry composition to 6.

### Example 16

A slurry composition for low-k film polishing was prepared in the same manner as in Example 13 except that the amount of triethanolamine added was adjusted to adjust the pH of the slurry composition to 7.

### Test Example 4

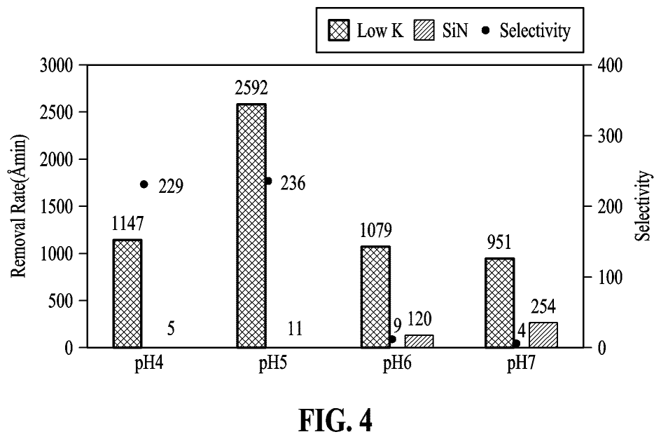

For each the slurry compositions of Examples 13 to 16, the low-k film removal rate, the SiN film removal rate, and a zeta potential value were measured, and the results thereof and the selectivity of the low-k film to the SiN film (low-k/SiN) were shown in Table 3 below and FIG. 4.

TABLE 3

| | Example 13 | Example 14 | Example 15 | Example 16 |
|---|---|---|---|---|
| pH | 4 | 5 | 6 | 7 |
| Low-k (Å/min) | 1147 | 2592 | 1079 | 951 |
| SiN (Å/min) | 5 | 11 | 120 | 254 |
| Selectivity | 229 | 236 | 9 | 4 |
| Zeta potential | +45 | +41 | +19 | +15 |
| [mV] | | | | |

Referring to Table 3 and FIG. 4, it may be confirmed that the low-k film was hydrophilized to secure the removal rate for the low-k film by adding triethanolamine which is a hydrophilic compound, as the low-k booster, however, as the content of the low-k booster added increases, the pH increases and the removal rate for the low-k film decreases. In addition, it may be confirmed that, as the pH decreases, the SiN removal rate decreases due to the enhancement of positive charge. However, if the pH becomes too low, the selectivity increases due to a decrease in the SiN removal rate, however, it is disadvantageous in that the sufficient low-k removal rate may not be secured. Therefore, it may be confirmed that the pH of the slurry composition is adjusted by appropriately adjusting the amount of the low-k booster to secure the excellent selectivity with the improvement of the low-k removal rate.

### 5. Change in Removal Rate and Selectivity According to Type of Dispersant

### Example 17

A polishing solution containing 2.5 wt % of colloidal ceria abrasive particles having a size of 70 nm, 5 wt % of formic acid as the dispersant, and the remainder of water was prepared.

An additive solution containing 0.02 wt % of poly(2-methacryloxyethyl)trimethylammonium chloride as the cationic polymer, 1 wt % of sorbitol as the SiN polishing inhibitor, 0.1 wt % of formic acid as the pH buffer, 0.6 wt % of triethanolamine as the low-k booster, and the remainder of water was prepared.

The polishing solution and the additive solution were mixed to prepare a slurry composition for low-k film polishing with a pH of 5.

### Example 18

A slurry composition for low-k film polishing was prepared in the same manner as in Example 17, except that 5 wt % of acetic acid was added as the dispersant.

### Example 19

A slurry composition for low-k film polishing was prepared in the same manner as in Example 17, except that 5 wt % of propionic acid was added as the dispersant.

### Example 20

A slurry composition for low-k film polishing was prepared in the same manner as in Example 17, except that 5 wt % of lactic acid was added as the dispersant.

### Test Example 5

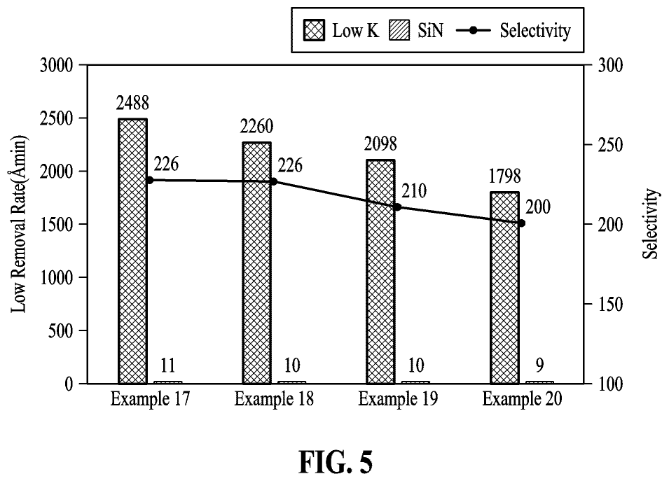

For each of the compositions of Examples 17 to 20, the low-k film removal rate, the SiN film removal rate, and the selectivity were measured and results thereof were shown in Table 4 below and FIG. 5.

TABLE 4

| | Example 17 | Example 18 | Example 19 | Example 20 |
|---|---|---|---|---|
| Dispersant type | Formic acid | Acetic acid | Propionic acid | Lactic acid |
| Number of carbon | 1 | 2 | 3 | 3 |
| atoms | | | | |
| Number of hydroxy | 1 | 1 | 1 | 2 |
| groups | | | | |
| Low-k (Å/min) | 2488 | 2260 | 2098 | 1798 |
| SiN (Å/min) | 11 | 10 | 10 | 9 |
| Selectivity | 226 | 226 | 210 | 200 |

Referring to Table 4 and FIG. 5, it may be confirmed that, as the number of carbon atoms and hydroxy groups in the dispersant increases, the low-k removal rate and the polishing selectivity decrease, and particularly, it is found that formic acid and acetic acid are superior in terms of the removal rate and the polishing selectivity.

While the embodiments are described with reference to drawings, it will be apparent to one of ordinary skill in the art that various alterations and modifications in form and details may be made in these embodiments without departing from the spirit and scope of the claims and their equivalents. For example, suitable results may be achieved if the described techniques are performed in a different order and/or if components in a described system, architecture, device, or circuit are combined in a different manner and/or replaced or supplemented by other components or their equivalents.

Therefore, other implementations, other embodiments, and equivalents to the claims are also within the scope of the following claims.

What is claimed is:

1. A slurry composition for low-k film polishing, the slurry composition comprising:
ceria abrasive particles;
a dispersant;
a SiN polishing inhibitor; and
a low-k booster,
wherein the dispersant is monomolecular organic acid.

2. The slurry composition of claim 1, further comprising:
at least one selected from the group consisting of a cationic polymer and a pH buffer.

3. The slurry composition of claim 1, wherein pH is 3.5 to 5.5.

4. The slurry composition of claim 1, wherein the ceria abrasive particles are calcined ceria abrasive particles or colloidal ceria abrasive particles.

5. The slurry composition of claim 4, wherein, when the calcined ceria abrasive particles are slurried, the calcined ceria abrasive particles have a size of 50 nm to 150 nm.

6. The slurry composition of claim 4, wherein, when the colloidal ceria abrasive particles are slurried, the colloidal ceria abrasive particles have a size of 20 nm to 100 nm.

7. The slurry composition of claim 1, wherein
the dispersant comprises one or more selected from the group consisting of organic acid having a structure represented by Chemical Formula 1, aromatic alpha hydroxy carboxylic acid, and pyridine carboxylic acid, and 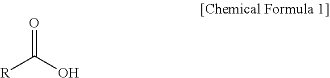
(where R is H or a methyl group)
the dispersant is included in an amount of 0.1 wt % to 30 wt % based on a total weight of the slurry composition.

8. The slurry composition of claim 2, wherein
the cationic polymer comprises one or more selected from the group consisting of poly(2-methacryloxyethyl)trimethylammonium chloride; poly(acrylamide 2-methacryloxyethyltrimethyl ammonium chloride); poly[2-(dimethylamino)ethyl methacrylate methyl chloride]; poly[3-acrylamidopropyl trimethylammonium chloride]; poly[3-methacrylamidopropyl trimethylammonium chloride]; poly[bis(2-chloroethyl) ether-alt-1,3-bis[3-(dimethylamino)propyl]urea]; a copolymer of acrylamide and quaternized dimethylammoniumethyl methacrylate; an acrylamide-dimethylaminoethyl methacrylate methyl chloride copolymer; a copolymer of vinylpyrrolidone and quaternized dimethylaminoethyl methacrylate; and a copolymer of vinylpyrrolidone and methacrylamidopropyl trimethylammonium, and
the cationic polymer is included in an amount of 0.001 wt % to 0.1 wt % based on a total weight of the slurry composition.

9. The slurry composition of claim 2, wherein
the pH buffer is organic acid,
the organic acid comprises at least one selected from the group consisting of formic acid, acetic acid, benzoic acid, oxalic acid, succinic acid, malic acid, maleic acid, malonic acid, citric acid, lactic acid, tricarballyic acid, tartaric acid, aspartic acid, glutaric acid, adipic acid, suberic acid, fumaric acid, phthalic acid, and salts thereof, and
the pH buffer is included in an amount of 0.01 wt % to 1 wt % based on a total weight of the slurry composition.

10. The slurry composition of claim 1, wherein the SiN polishing inhibitor comprises one or more selected from the group consisting of maltitol, lactitol, threitol, erythritol, ribitol, xylitol, arabitol, adonitol, sorbitol, talitol, mannitol, iditol, allodulcitol, dulcitol, galactitol, sedoheptitol, and perseitol.

11. The slurry composition of claim 1, wherein the SiN polishing inhibitor is included in an amount of 0.1 wt % to 5 wt % based on a total weight of the slurry composition.

12. The slurry composition of claim 1, wherein
the low-k booster is an amine-based compound, and
the amine-based compound comprises one or more selected from the group consisting of triethanolamine, aminomethyl propanol, ammonium hydroxide, lysine, arginine, and histidine.

13. The slurry composition of claim 1, wherein the low-k booster is included in an amount of 0.01 wt % to 1 wt % based on a total weight of the slurry composition.
